(19) United States
(12) Patent Application Publication
(10) Pub. No.: US 2019/0042370 A1
(43) Pub. Date: Feb. 7, 2019

(54) ALTERNATIVE STORAGE LOCATION PROTOCOL FOR A DISTRIBUTED STORAGE NETWORK

(71) Applicant: International Business Machines Corporation, Armonk, NY (US)

(72) Inventors: Jason K. Resch, Chicago, IL (US); Wesley B. Leggette, Chicago, IL (US)

(21) Appl. No.: 16/158,645

(22) Filed: Oct. 12, 2018

Related U.S. Application Data
(63) Continuation-in-part of application No. 15/350,672, filed on Nov. 14, 2016.
Application No. 15/350,672 is a continuation of application No. 14/527,139, filed on Oct. 29, 2014, now Pat. No. 9,594,639.
(60) Provisional application No. 61/924,196, filed on Jan. 6, 2014.

(51) Int. Cl. G06F 11/14; G06F 17/30; H04L 29/08; H03M 13/35; G06F 3/06; G06F 11/10

(52) U.S. Cl. CPC G06F 11/1435; G06F 17/30; H04L 67/1097; H03M 13/353; G06F 3/067; G06F 3/064; G06F 3/0619; G06F 11/1076; G06F 2211/1028

(57) ABSTRACT

A method begins by a processing module of a dispersed storage network (DSN) receiving a write request for a data object, encoding a data segment of the data object to produce a write threshold number of encoded data slices and determining whether a write threshold number of storage units is available for storing the encoded data slices. In response to determining that a write threshold number of storage units is available, the method continues by selecting a write threshold number of storage units from the storage units available for storing the encoded data slices. The method continues by generating a vault source name for the data segment and associating the vault source name of the data segment with a data identifier and finishes by issuing write slice requests to the storage units, where each write slice request includes the vault source name and an associated encoded data slice of the encoded data slices.

The present U.S. Utility patent application claims priority pursuant to 35 U. S.C. § 120 as a continuation-in-part of U.S. Utility application Ser. No. 15/350,672, entitled “CONFIGURING STORAGE RESOURCES OF A DISPERSED STORAGE NETWORK”, filed Nov. 14, 2016, which claims priority pursuant to 35 U.S.C. § 120 as a continuation of U.S. Utility application Ser. No. 14/527,139, entitled “CONFIGURING STORAGE RESOURCES OF A DISPERSED STORAGE NETWORK”, filed Oct. 29, 2014, now U.S. Pat. No. 9,594,639 issued on Mar. 14, 2017, which claims priority pursuant to 35 U.S.C. § 119(e) to U.S. Provisional Application No. 61/924,196, entitled “CONFIGURING STORAGE SLOTS IN A DISPERSED STORAGE NETWORK”, filed Jan. 6, 2014, now expired, all of which are hereby incorporated herein by reference in their entirety and made part of the present U.S. Utility Patent Application for all purposes.

### STATEMENT REGARDING FEDERALLY SPONSORED RESEARCH OR DEVELOPMENT

Not applicable.

### INCORPORATION-BY-REFERENCE OF MATERIAL SUBMITTED ON A COMPACT DISC

Not applicable.

### BACKGROUND OF THE INVENTION

### Technical Field of the Invention

This invention relates generally to computer networks and more particularly to dispersing error encoded data.

### Description of Related Art

Computing devices are known to communicate data, process data, and/or store data. Such computing devices range from wireless smart phones, laptops, tablets, personal computers (PC), work stations, and video game devices, to data centers that support millions of web searches, stock trades, or on-line purchases every day. In general, a computing device includes a central processing unit (CPU), a memory system, user input/output interfaces, peripheral device interfaces, and an interconnecting bus structure.

As is further known, a computer may effectively extend its CPU by using “cloud computing” to perform one or more computing functions (e.g., a service, an application, an algorithm, an arithmetic logic function, etc.) on behalf of the computer. Further, for large services, applications, and/or functions, cloud computing may be performed by multiple cloud computing resources in a distributed manner to improve the response time for completion of the service, application, and/or function. For example, Hadoop is an open source software framework that supports distributed applications enabling application execution by thousands of computers.

In addition to cloud computing, a computer may use “cloud storage” as part of its memory system. As is known, cloud storage enables a user, via its computer, to store files, applications, etc. on an Internet storage system. The Internet storage system may include a RAID (redundant array of independent disks) system and/or a dispersed storage system that uses an error correction scheme to encode data for storage.

### BRIEF DESCRIPTION OF THE SEVERAL VIEWS OF THE DRAWING(S)

FIG. 1 is a schematic block diagram of an embodiment of a dispersed or distributed storage network (DSN) in accordance with the present invention;

FIG. 2 is a schematic block diagram of an embodiment of a computing core in accordance with the present invention;

FIG. 3 is a schematic block diagram of an example of dispersed storage error encoding of data in accordance with the present invention;

FIG. 4 is a schematic block diagram of a generic example of an error encoding function in accordance with the present invention;

FIG. 5 is a schematic block diagram of a specific example of an error encoding function in accordance with the present invention;

FIG. 6 is a schematic block diagram of an example of a slice name of an encoded data slice (EDS) in accordance with the present invention;

FIG. 7 is a schematic block diagram of an example of dispersed storage error decoding of data in accordance with the present invention;

FIG. 8 is a schematic block diagram of a generic example of an error decoding function in accordance with the present invention;

FIGS. 9A and 9B are schematic block diagrams of an embodiment of a dispersed storage network (DSN) in accordance with the present invention;

FIG. 9C is a flowchart illustrating an example of storing data in accordance with the present invention;

FIG. 9D is a flowchart illustrating an example of retrieving data in accordance with the present invention;

### DETAILED DESCRIPTION OF THE INVENTION

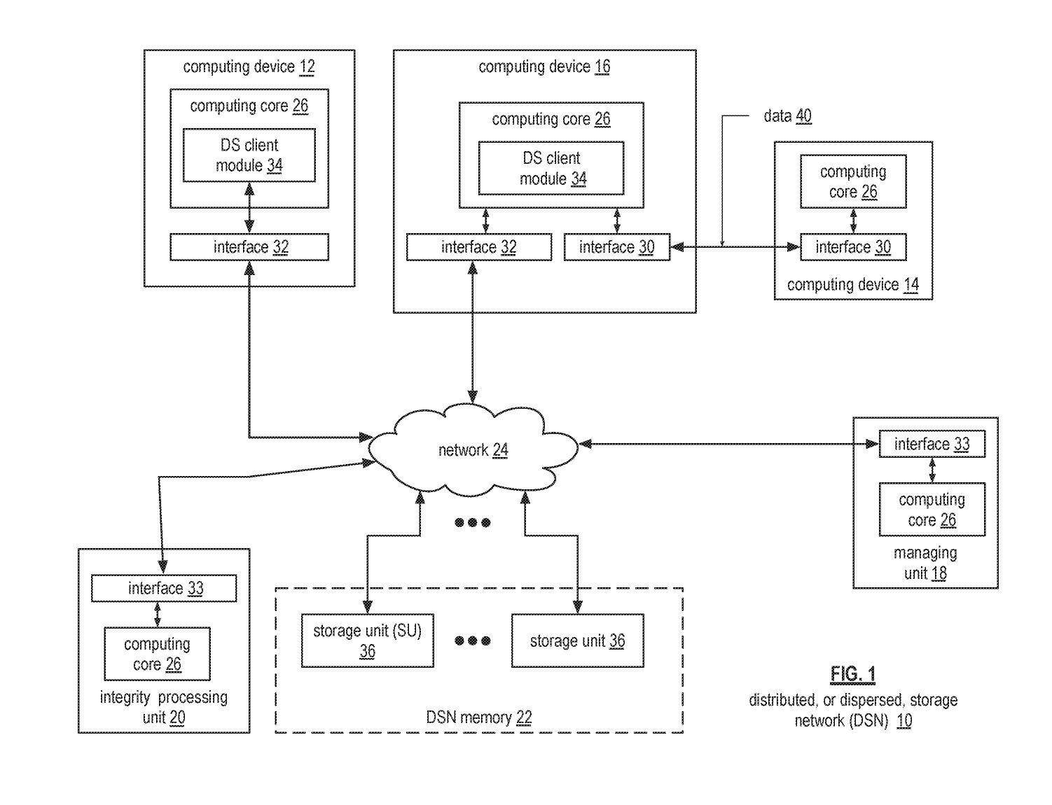

FIG. 1 is a schematic block diagram of an embodiment of a dispersed, or distributed, storage network (DSN) 10 that includes a plurality of computing devices 12-16, a managing unit 18, an integrity processing unit 20, and a DSN memory 22. The components of the DSN 10 are coupled to a network 24, which may include one or more wireless and/or wire lined communication systems; one or more non-public intranet systems and/or public internet systems; and/or one or more local area networks (LAN) and/or wide area networks (WAN).

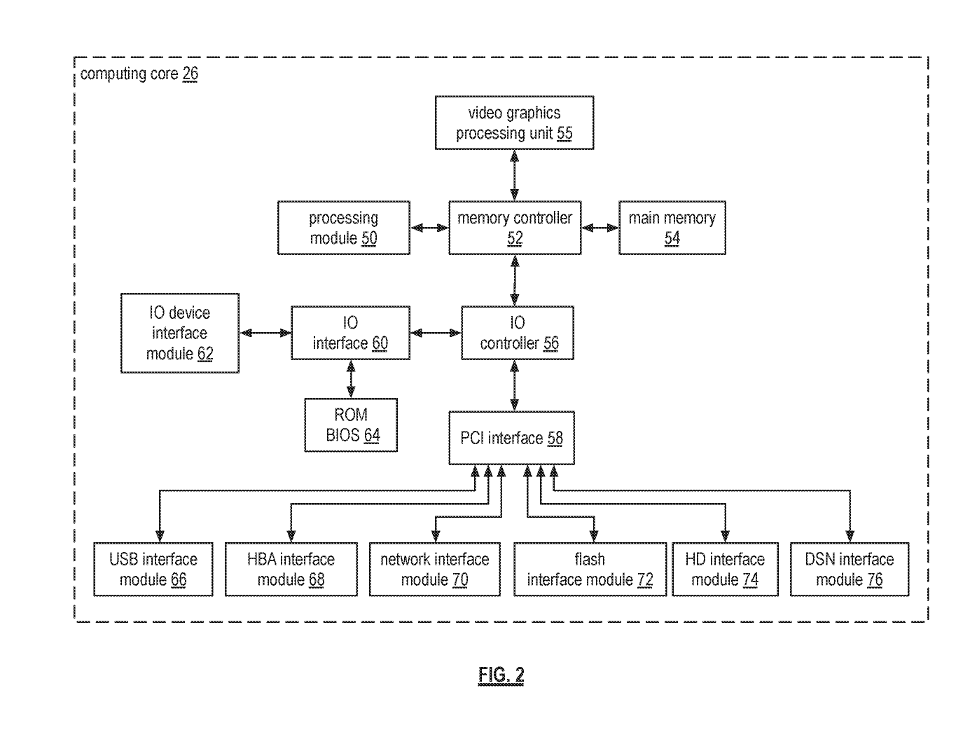

The DSN memory 22 includes a plurality of storage units 36 that may be located at geographically different sites (e.g., one in Chicago, one in Milwaukee, etc.), at a common site, or a combination thereof. For example, if the DSN memory 22 includes eight storage units 36, each storage unit is located at a different site. As another example, if the DSN memory 22 includes eight storage units 36, all eight storage units are located at the same site. As yet another example, if the DSN memory 22 includes eight storage units 36, a first pair of storage units are at a first common site, a second pair of storage units are at a second common site, a third pair of storage units are at a third common site, and a fourth pair of storage units are at a fourth common site. Note that a DSN memory 22 may include more or less than eight storage units 36. Further note that each storage unit 36 includes a computing core (as shown in FIG. 2, or components thereof) and a plurality of memory devices for storing dispersed error encoded data.

Each of the computing devices 12-16, the managing unit 18, and the integrity processing unit 20 include a computing core 26, which includes network interfaces 30-33. Computing devices 12-16 may each be a portable computing device and/or a fixed computing device. A portable computing device may be a social networking device, a gaming device, a cell phone, a smart phone, a digital assistant, a digital music player, a digital video player, a laptop computer, a handheld computer, a tablet, a video game controller, and/or any other portable device that includes a computing core. A fixed computing device may be a computer (PC), a computer server, a cable set-top box, a satellite receiver, a television set, a printer, a fax machine, home entertainment equipment, a video game console, and/or any type of home or office computing equipment. Note that each of the managing unit 18 and the integrity processing unit 20 may be separate computing devices, may be a common computing device, and/or may be integrated into one or more of the computing devices 12-16 and/or into one or more of the storage units 36.

Each interface 30, 32, and 33 includes software and hardware to support one or more communication links via the network 24 indirectly and/or directly. For example, interface 30 supports a communication link (e.g., wired, wireless, direct, via a LAN, via the network 24, etc.) between computing devices 14 and 16. As another example, interface 32 supports communication links (e.g., a wired connection, a wireless connection, a LAN connection, and/or any other type of connection to/from the network 24) between computing devices 12 and 16 and the DSN memory 22. As yet another example, interface 33 supports a communication link for each of the managing unit 18 and the integrity processing unit 20 to the network 24.

Computing devices 12 and 16 include a dispersed storage (DS) client module 34, which enables the computing device to dispersed storage error encode and decode data (e.g., data 40) as subsequently described with reference to one or more of FIGS. 3-8. In this example embodiment, computing device 16 functions as a dispersed storage processing agent for computing device 14. In this role, computing device 16 dispersed storage error encodes and decodes data on behalf of computing device 14. With the use of dispersed storage error encoding and decoding, the DSN 10 is tolerant of a significant number of storage unit failures (the number of failures is based on parameters of the dispersed storage error encoding function) without loss of data and without the need for a redundant or backup copies of the data. Further, the DSN 10 stores data for an indefinite period of time without data loss and in a secure manner (e.g., the system is very resistant to unauthorized attempts at accessing the data).

In operation, the managing unit 18 performs DS management services. For example, the managing unit 18 establishes distributed data storage parameters (e.g., vault creation, distributed storage parameters, security parameters, billing information, user profile information, etc.) for computing devices 12-14 individually or as part of a group of user devices. As a specific example, the managing unit 18 coordinates creation of a vault (e.g., a virtual memory block associated with a portion of an overall namespace of the DSN) within the DSN memory 22 for a user device, a group of devices, or for public access and establishes per vault dispersed storage (DS) error encoding parameters for a vault. The managing unit 18 facilitates storage of DS error encoding parameters for each vault by updating registry information of the DSN 10, where the registry information may be stored in the DSN memory 22, a computing device 12-16, the managing unit 18, and/or the integrity processing unit 20.

The managing unit 18 creates and stores user profile information (e.g., an access control list (ACL)) in local memory and/or within memory of the DSN memory 22. The user profile information includes authentication information, permissions, and/or the security parameters. The security parameters may include encryption/decryption scheme, one or more encryption keys, key generation scheme, and/or data encoding/decoding scheme.

The managing unit 18 creates billing information for a particular user, a user group, a vault access, public vault access, etc. For instance, the managing unit 18 tracks the number of times a user accesses a non-public vault and/or public vaults, which can be used to generate a per-access billing information. In another instance, the managing unit 18 tracks the amount of data stored and/or retrieved by a user device and/or a user group, which can be used to generate a per-data-amount billing information.

As another example, the managing unit 18 performs network operations, network administration, and/or network maintenance. Network operations includes authenticating user data allocation requests (e.g., read and/or write requests), managing creation of vaults, establishing authentication credentials for user devices, adding/deleting components (e.g., user devices, storage units, and/or computing devices with a DS client module 34) to/from the DSN 10, and/or establishing authentication credentials for the storage units 36. Network administration includes monitoring devices and/or units for failures, maintaining vault information, determining device and/or unit activation status, determining device and/or unit loading, and/or determining any other system level operation that affects the performance level of the DSN 10. Network maintenance includes facilitating replacing, upgrading, repairing, and/or expanding a device and/or unit of the DSN 10.

The integrity processing unit 20 performs rebuilding of ‘bad’ or missing encoded data slices. At a high level, the integrity processing unit 20 performs rebuilding by periodically attempting to retrieve/list encoded data slices, and/or slice names of the encoded data slices, from the DSN memory 22. For retrieved encoded slices, they are checked for errors due to data corruption, outdated version, etc. If a slice includes an error, it is flagged as a ‘bad’ slice. For encoded data slices that were not received and/or not listed, they are flagged as missing slices. Bad and/or missing slices are subsequently rebuilt using other retrieved encoded data slices that are deemed to be good slices to produce rebuilt slices. The rebuilt slices are stored in the DSN memory 22.

FIG. 2 is a schematic block diagram of an embodiment of a computing core 26 that includes a processing module 50, a memory controller 52, main memory 54, a video graphics processing unit 55, an input/output (IO) controller 56, a peripheral component interconnect (PCI) interface 58, an IO interface module 60, at least one IO device interface module 62, a read only memory (ROM) basic input output system (BIOS) 64, and one or more memory interface modules. The one or more memory interface module(s) includes one or more of a universal serial bus (USB) interface module 66, a host bus adapter (HBA) interface module 68, a network interface module 70, a flash interface module 72, a hard drive interface module 74, and a DSN interface module 76.

The DSN interface module 76 functions to mimic a conventional operating system (OS) file system interface (e.g., network file system (NFS), flash file system (FFS), disk file system (DFS), file transfer protocol (FTP), web-based distributed authoring and versioning (WebDAV), etc.) and/or a block memory interface (e.g., small computer system interface (SCSI), internet small computer system interface (iSCSI), etc.). The DSN interface module 76 and/or the network interface module 70 may function as one or more of the interface 30-33 of FIG. 1. Note that the IO device interface module 62 and/or the memory interface modules 66-76 may be collectively or individually referred to as IO ports.

FIG. 3 is a schematic block diagram of an example of dispersed storage error encoding of data. When a computing device 12 or 16 has data to store it disperse storage error encodes the data in accordance with a dispersed storage error encoding process based on dispersed storage error encoding parameters. The dispersed storage error encoding parameters include an encoding function (e.g., information dispersal algorithm, Reed-Solomon, Cauchy Reed-Solomon, systematic encoding, non-systematic encoding, on-line codes, etc.), a data segmenting protocol (e.g., data segment size, fixed, variable, etc.), and per data segment encoding values. The per data segment encoding values include a total, or pillar width, number (T) of encoded data slices per encoding of a data segment (i.e., in a set of encoded data slices); a decode threshold number (D) of encoded data slices of a set of encoded data slices that are needed to recover the data segment; a read threshold number (R) of encoded data slices to indicate a number of encoded data slices per set to be read from storage for decoding of the data segment; and/or a write threshold number (W) to indicate a number of encoded data slices per set that must be accurately stored before the encoded data segment is deemed to have been properly stored. The dispersed storage error encoding parameters may further include slicing information (e.g., the number of encoded data slices that will be created for each data segment) and/or slice security information (e.g., per encoded data slice encryption, compression, integrity checksum, etc.).

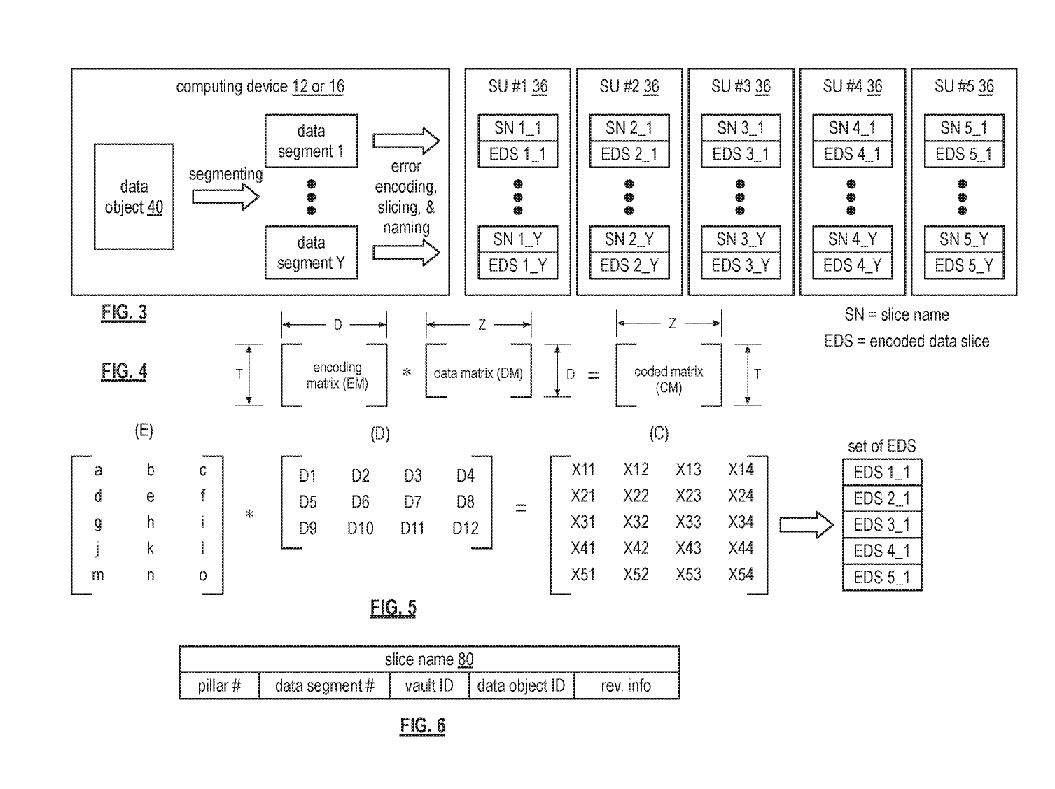

In the present example, Cauchy Reed-Solomon has been selected as the encoding function (a generic example is shown in FIG. 4 and a specific example is shown in FIG. 5); the data segmenting protocol is to divide the data object into fixed sized data segments; and the per data segment encoding values include: a pillar width of 5, a decode threshold of 3, a read threshold of 4, and a write threshold of 4. In accordance with the data segmenting protocol, the computing device 12 or 16 divides the data (e.g., a file (e.g., text, video, audio, etc.), a data object, or other data arrangement) into a plurality of fixed sized data segments (e.g., 1 through Y of a fixed size in range of Kilo-bytes to Tera-bytes or more). The number of data segments created is dependent of the size of the data and the data segmenting protocol.

The computing device 12 or 16 then disperse storage error encodes a data segment using the selected encoding function (e.g., Cauchy Reed-Solomon) to produce a set of encoded data slices. FIG. 4 illustrates a generic Cauchy Reed-Solomon encoding function, which includes an encoding matrix (EM), a data matrix (DM), and a coded matrix (CM). The size of the encoding matrix (EM) is dependent on the pillar width number (T) and the decode threshold number (D) of selected per data segment encoding values. To produce the data matrix (DM), the data segment is divided into a plurality of data blocks and the data blocks are arranged into D number of rows with Z data blocks per row. Note that Z is a function of the number of data blocks created from the data segment and the decode threshold number (D). The coded matrix is produced by matrix multiplying the data matrix by the encoding matrix.

FIG. 5 illustrates a specific example of Cauchy Reed-Solomon encoding with a pillar number (T) of five and decode threshold number of three. In this example, a first data segment is divided into twelve data blocks (D1-D12). The coded matrix includes five rows of coded data blocks, where the first row of X11-X14 corresponds to a first encoded data slice (EDS 1_1), the second row of X21-X24 corresponds to a second encoded data slice (EDS 2 1), the third row of X31-X34 corresponds to a third encoded data slice (EDS 3_1), the fourth row of X41-X44 corresponds to a fourth encoded data slice (EDS 4_1), and the fifth row of X51-X54 corresponds to a fifth encoded data slice (EDS 5_1). Note that the second number of the EDS designation corresponds to the data segment number.

Returning to the discussion of FIG. 3, the computing device also creates a slice name (SN) for each encoded data slice (EDS) in the set of encoded data slices. A typical format for a slice name is shown in FIG. 6. As shown, the slice name (SN) includes a pillar number of the encoded data slice (e.g., one of 1-T), a data segment number (e.g., one of 1-Y), a vault identifier (ID), a data object identifier (ID), and may further include revision level information of the encoded data slices. The slice name functions as, at least part of, a DSN address for the encoded data slice for storage and retrieval from the DSN memory 22.

As a result of encoding, the computing device 12 or 16 produces a plurality of sets of encoded data slices, which are provided with their respective slice names to the storage units for storage. As shown, the first set of encoded data slices includes EDS 1_1 through EDS 5_1 and the first set of slice names includes SN 1_1 through SN 5_1 and the last set of encoded data slices includes EDS 1_Y through EDS 5_Y and the last set of slice names includes SN 1_Y through SN 5_Y.

FIG. 7 is a schematic block diagram of an example of dispersed storage error decoding of a data object that was dispersed storage error encoded and stored in the example of FIG. 4. In this example, the computing device 12 or 16 retrieves from the storage units at least the decode threshold number of encoded data slices per data segment. As a specific example, the computing device retrieves a read threshold number of encoded data slices.

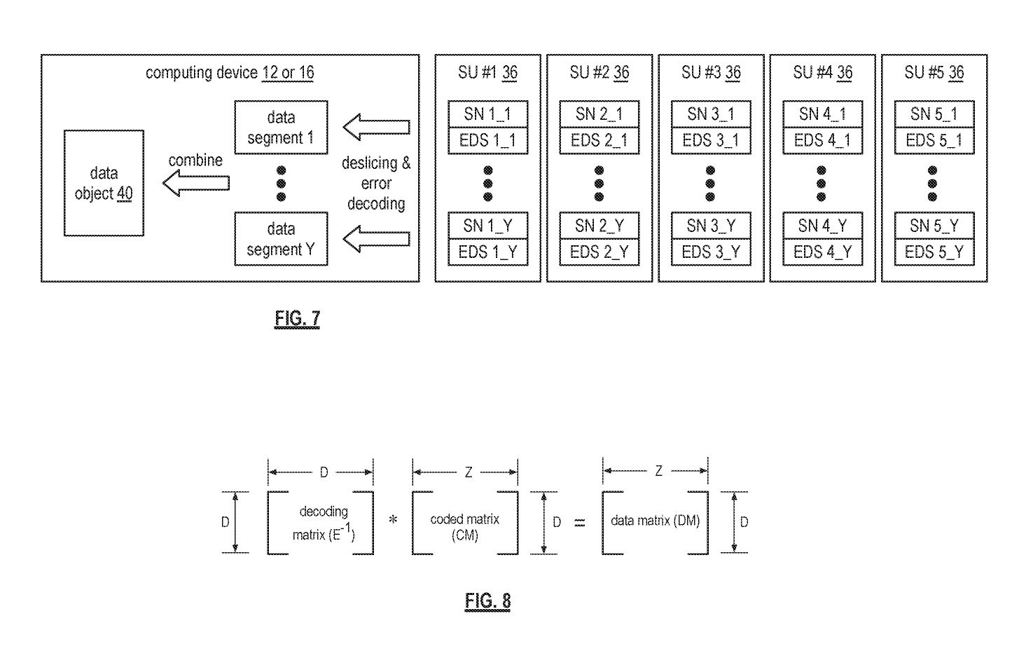

To recover a data segment from a decode threshold number of encoded data slices, the computing device uses a decoding function as shown in FIG. 8. As shown, the decoding function is essentially an inverse of the encoding function of FIG. 4. The coded matrix includes a decode threshold number of rows (e.g., three in this example) and the decoding matrix in an inversion of the encoding matrix that includes the corresponding rows of the coded matrix. For example, if the coded matrix includes rows 1, 2, and 4, the encoding matrix is reduced to rows 1, 2, and 4, and then inverted to produce the decoding matrix.

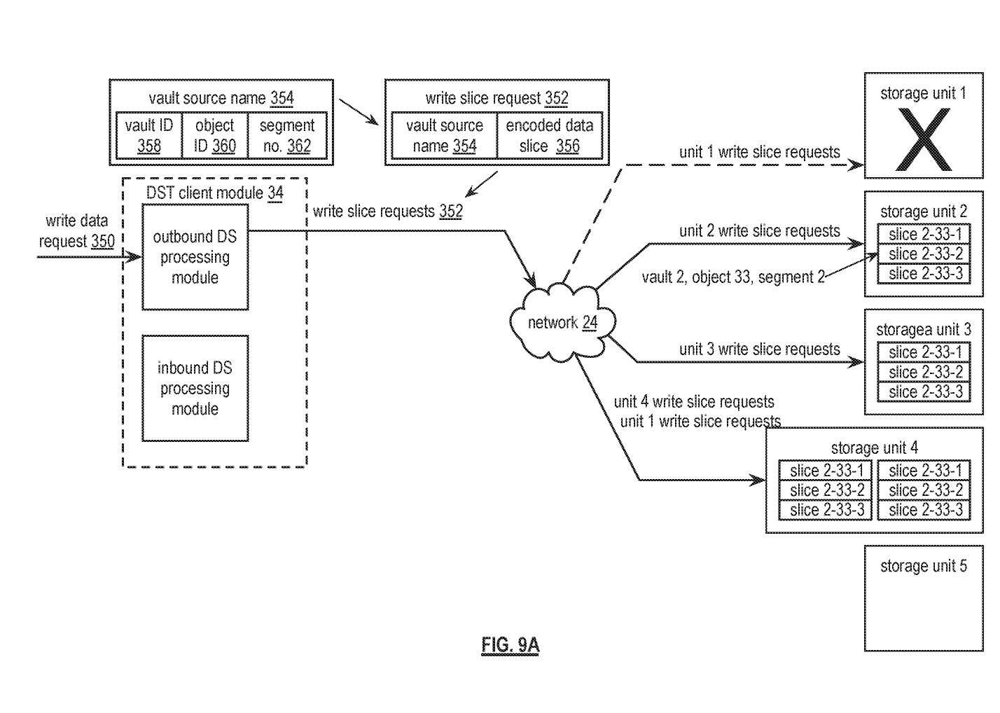

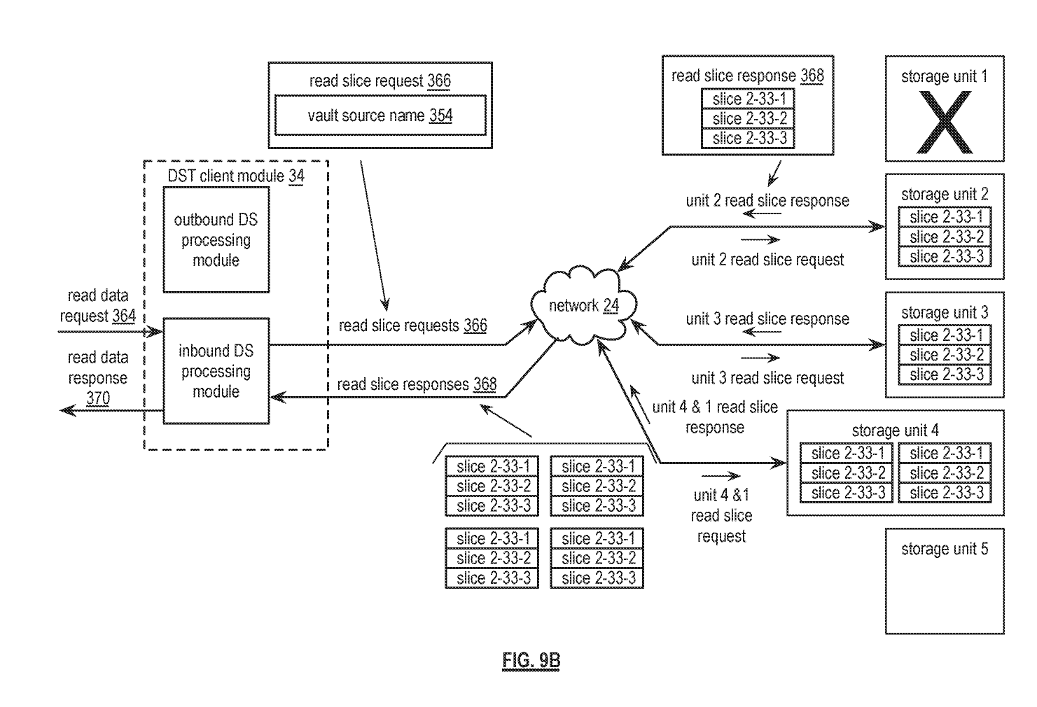

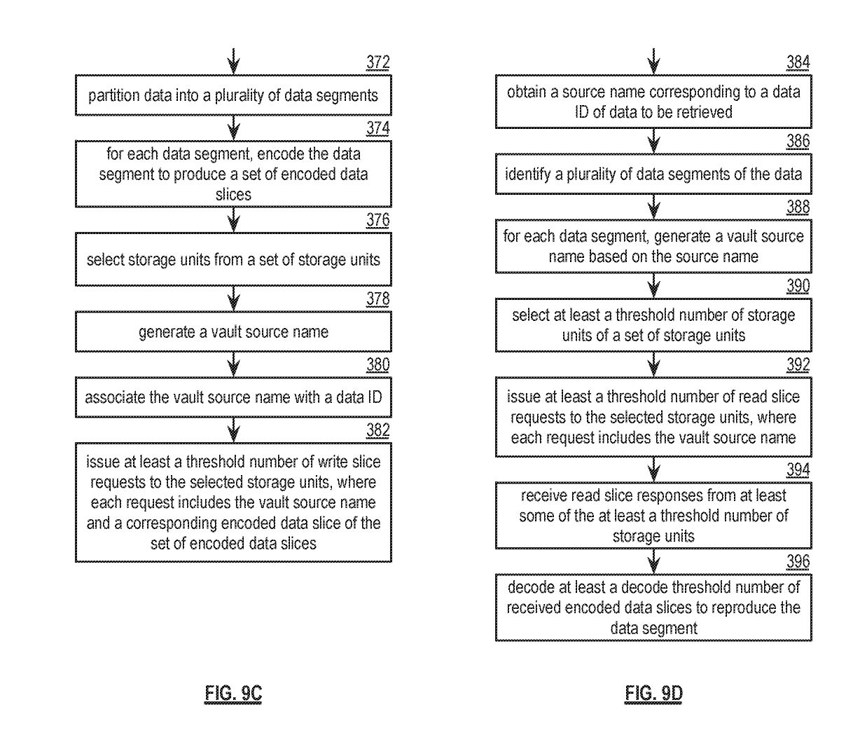

FIGS. 9A and 9B are schematic block diagrams of an embodiment of a dispersed storage network (DSN) that includes the distributed storage (DS) client module 34 of FIG. 1, the network 24 of FIG. 1, and a set of storage units 1-5. The set of storage units includes one or more of the storage units 36 of FIG. 1. The DS client module 34 includes the outbound dispersed storage (DS) processing module 12 or 16 of FIG. 3. The DSN functions to store data to the set of storage units 1-5 and to retrieve the data from the set of storage 1-5.

In particular, FIG. 9A illustrates an example of the storing of the data to the set of storage units 1-5. As a specific example, the DS client module 34 receives a write data request 350 from a requesting entity. The write data request 350 includes one or more of the data for storage and a data identifier (ID) of the data. The outbound computing device 12 or 16 partitions the data into a plurality of data segments in accordance with a data segmentation scheme (e.g., uniform data segment sizes, data segment sizes that ramp up or down). For each data segment, the outbound computing device 12 or 16 dispersed storage error encodes the data segment to produce a set of encoded data slices in accordance with dispersal parameters. The dispersal parameters includes one or more of an information dispersal algorithm (IDA) width, a write threshold number, a read threshold number, a decode threshold number, and an encoding matrix. For example, the outbound computing device 12 or 16 encodes the data segment to produce 5 encoded data slices when the IDA width is 5.

Having produced the plurality of sets of encoded data slices, the outbound computing device 12 or 16, for each set of encoded data slices, selects a group of storage units for storage of at least a threshold number (e.g., the write threshold number, the read threshold number, the decode threshold number, another threshold number) of encoded data slices of the set of encoded data slices. The selecting may be based on one or more of a predetermination, a mapping of slice pillar numbers to storage units, a previously received write slice response, a received error message, a unit rotation algorithm, a storage unit availability level, a storage unit reliability level, a storage unit performance level, a storage unit foster storage location status (e.g., for storage of foster encoded data slices), and a maximum number of pillars associated with each storage unit. Foster encoded data slices are associated with additional encoded data slices to be at least temporarily stored in a storage unit available for foster slice storage. For example, the outbound computing device 12 or 16 determines to select the group of storage units for storage of the write threshold number (e.g., 4 encoded data slices) of the set of encoded data slices (e.g., 5 encoded data slices) where storage unit 2 is selected for storage of a first encoded data slice, storage unit 3 is selected for storage of a second encoded data slice, and storage unit 4 is selected for storage of third and fourth encoded data slices when storage unit 1 is unavailable, storage units 2-4 are available, storage unit 4 is available to store foster slices, and storage unit 5 is associated with an unfavorable performance level.

Having selected the group of storage units for storage of the threshold number of encoded data slices, the outbound computing device 12 or 16 generates a vault source name 354 for the set of encoded data slices, where the vault source name 354 includes one or more of a vault ID 358, an object ID 360, and a segment number 362. The vault ID 358 includes a predetermined number associated with one or more of the data ID and a requesting entity ID of the requesting entity. The object ID 360 includes a unique number (e.g., randomly generated, deterministically generated based on the data and/or the data ID) to be associated with the data ID. The segment number 362 includes a designator associated with the particular set of encoded data slices of the plurality of sets of encoded data slices. The outbound computing device 12 or 16 updates one or more of a DSN directory and a dispersed hierarchical index to associate at least a portion (e.g., the vault ID and the object ID) of the vault source name 354 with the data ID to facilitate subsequent retrieval of the data.

Having generated the vault source name 354 for the set of encoded data slices, the outbound computing device 12 or 16 issues, via the network 24, a threshold number of write slice requests 352 to the selected group of storage units, where the threshold number (e.g., the write threshold number) of write slice requests 332 includes the threshold number of encoded data slices 356 associated with the selected group of storage units and the vault source name 354. Hereafter, steps including one or more of writing, reading, issuing, receiving, accessing, storing etc., may inherently utilize the network 24 to transfer associated one or more of messages, requests, responses, status, information etc., even when not explicitly stated.

Each storage unit of the selected group of storage units stores received encoded data slices 356 and the vault source name 354 when the vault source name falls within a range of assigned vault source names for the set of storage units. For example, storage unit 2 stores encoded data slices for segments 1-3 of object 33 associated with vault 2, storage unit 3 stores more encoded data slices for the segments 1-3 of the object 33 associated with the vault 2, and storage unit 4 stores still more encoded data slices for two pillars for the segments 1-3 of the object 33 associated with the vault 2. As such, each storage unit accepts and stores encoded data slices associated with any pillar of each set of encoded data slices when the vault source names fall within the range of assigned vault source names for the set of storage units.

FIG. 9B illustrates an example of the retrieving of the data to the set of storage units 1-5. As a specific example, the DST client module 34 receives a read data request 364 that includes the data ID. The inbound computing device 12 or 16 obtains a source name corresponding to the data ID. For example, the inbound computing device 12 or 16 accesses at least one of the DSN directory and the dispersed hierarchical network utilizing the data ID to retrieve the source name that includes the vault ID and the object ID. As another example, the inbound DS processing extracts the source name from the read data request 364 when the source name is included in the read data request 364.

Having obtained the source name, the inbound DST processing module identifies the plurality of data segments associated with the data. The identifying includes at least one of accessing a first data segment (e.g., retrieving at least a decode threshold number of encoded data slices of the first data segment and decoding the decode threshold number of encoded data slices to reproduce the first data segment) and accessing a segment allocation table. For each data segment, the inbound computing device 12 or 16 generates a vault source name 354 based on the source name and identity of the data segment. For example, the inbound computing device 12 or 16 appends a data segment number of a particular data segment to the source name to produce the vault source name 354 associated with the particular data segment.

Having generated the vault source name 354 for the data segment, the inbound computing device 12 or 16 selects another group of storage units of the storage unit set includes at least another threshold number (e.g., the read threshold number) of storage locations. The other group of storage units may be substantially the same as the group of storage units. The selecting may be based on one or more of received error messages, a storage unit performance level, a storage unit availability level, a storage unit reliability level, a storage unit assignment table lookup, a predetermination, initiating a query to the set of storage units, receiving a query response, and accessing a foster storage unit list.

Having selected the other group of storage units, the inbound computing device 12 or 16 issues (e.g., generates and sends), via the network 24, at least a threshold number (e.g., the read threshold number) of read slice requests 366 to the other group of storage units, where each read slice request 366 includes the vault source name 354 of the data segment. In an instance, each single read slice request 366 may include vault source names associated with two or more data segments of the plurality of data segments. The other group of storage units receives the at least a threshold number of read slice requests 366 and issues, via the network 24, corresponding read slice responses 368, where a read slice response 368 includes one or more encoded data slices associated with slice names that fall within the range of slice names associated with the vault source name of an associated read slice request.

The inbound computing device 12 or 16 receives read slice responses 368 from the other group of storage units. The inbound computing device 12 or 16 , for each data segment, decodes a decode threshold number of received encoded data slices of the read slice responses 368 to reproduce a corresponding data segment. The inbound computing device 12 or 16 aggregates a plurality of reproduced data segments to reproduce the data. The inbound computing device 12 or 16 issues a read data response 370 to a requesting entity, where the read data response 370 includes the reproduced data.

FIG. 9C is a flowchart illustrating an example of storing data. The method begins at step 372 where a processing module (e.g., of a distributed storage and task (DST) client module) partitions data into a plurality of data segments in accordance with a segmentation scheme. The method continues at step 374 where, for each data segment, the processing module encodes the data using a dispersed storage error coding function and in accordance with dispersal parameters to produce a set of encoded data slices. The method continues at step 376 where the processing module selects storage units from the set of storage units. For example, the processing module selects a write threshold number of available storage units based on one or more of an availability indicator, a write slice response, a query, a query response, and a predetermination. As another example, the processing module selects a write threshold minus one number of available storage units when the write threshold number of available storage units is not available.

The method continues at step 378 where the processing module generates a vault source name for the data segment based on one or more of a vault identifier (ID), a data ID of the data, and an object ID associated with the data ID. The method continues at step 3 where the processing module associates the vault source name of each data segment of the plurality of data segments with the data ID. For example, the processing module updates a dispersed storage network (DSN) directory to associate a source name portion of a vault source name with the data ID.

The method continues at step 3 where the processing module issues at least a threshold number of write slice requests to the selected storage units, where each write slice request includes the vault source name and a corresponding encoded data slice of the set of encoded data slices. For example, the processing module generates a write threshold number of write slice requests that includes a write threshold number of encoded data slices of the set of encoded data slices and where each write slice request includes the (same) vault source name. Alternatively, or in a addition to, the processing module generates a write slice requests to include a slice name associated with an encoded data slice, where the slice name includes the vault source name and a pillar index number associated with a corresponding pillar index number of an information dispersal algorithm (IDA) width number of encoded data slices of the set of encoded data slices.

FIG. 9D is a flowchart illustrating an example of retrieving data. The method begins at step 384 where a processing module (e.g., of a DS client module) obtains a source name corresponding to a data identifier (ID) of data to be retrieved from a dispersed storage network (DSN). For example, the processing module accesses a DSN directory utilizing the data ID to recover the source name. The method continues at step 386 where the processing module identifies a plurality of data segments of the data. The identifying includes at least one of accessing a segment allocation table and accessing a first data segment of the plurality of data segments.

The method continues at step 388 where, for each data segment, the processing module generates a vault source name based on the source name. For example, the processing module of appends a segment number corresponding to the data segment to the source name to produce the vault source name. The method continues at step 390 where the processing module selects at least a threshold number of storage units of a set of storage units. The selecting may be based on one or more of a storage unit availability level, a storage unit reliability level, a storage unit performance level, a storage unit preference table, initiating a query, receiving a query response, and a predetermination. For example, the processing module selects a read threshold number of storage units where each of the storage units is associated with a performance level greater than a performance threshold level.

The method continues at step 392 where the processing module issues, for the data segment, at least a threshold number of read slice requests to the selected storage units, where each read slice request includes the vault source name associated with the data segment. The method continues at step 394 where the processing module receives read slice responses from at least some of the at least a threshold number of storage units. The method continues at step 396 where the processing module decodes, for each data segment, at least a decode threshold number of received encoded data slices of the read slice responses to reproduce the data segment. Alternatively, or in addition to, the processing module aggregates a plurality of reproduced data segments to reproduce the data.

It is noted that terminologies as may be used herein such as bit stream, stream, signal sequence, etc. (or their equivalents) have been used interchangeably to describe digital information whose content corresponds to any of a number of desired types (e.g., data, video, speech, text, graphics, audio, etc. any of which may generally be referred to as ‘data’).

As may be used herein, the terms “substantially” and “approximately” provide an industry-accepted tolerance for its corresponding term and/or relativity between items. For some industries, an industry-accepted tolerance is less than one percent and, for other industries, the industry-accepted tolerance is 10 percent or more. Other examples of industry-accepted tolerance range from less than one percent to fifty percent. Industry-accepted tolerances correspond to, but are not limited to, component values, integrated circuit process variations, temperature variations, rise and fall times, thermal noise, dimensions, signaling errors, dropped packets, temperatures, pressures, material compositions, and/or performance metrics. Within an industry, tolerance variances of accepted tolerances may be more or less than a percentage level (e.g., dimension tolerance of less than +/−1%). Some relativity between items may range from a difference of less than a percentage level to a few percent. Other relativity between items may range from a difference of a few percent to magnitude of differences.

As may also be used herein, the term(s) “configured to”, “operably coupled to”, “coupled to”, and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”.

As may even further be used herein, the term “configured to”, “operable to”, “coupled to”, or “operably coupled to” indicates that an item includes one or more of power connections, input(s), output(s), etc., to perform, when activated, one or more its corresponding functions and may further include inferred coupling to one or more other items. As may still further be used herein, the term “associated with”, includes direct and/or indirect coupling of separate items and/or one item being embedded within another item.

As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1. As may be used herein, the term “compares unfavorably”, indicates that a comparison between two or more items, signals, etc., fails to provide the desired relationship.

As may be used herein, one or more claims may include, in a specific form of this generic form, the phrase “at least one of a, b, and c” or of this generic form “at least one of a, b, or c”, with more or less elements than “a”, “b”, and “c”. In either phrasing, the phrases are to be interpreted identically. In particular, “at least one of a, b, and c” is equivalent to “at least one of a, b, or c” and shall mean a, b, and/or c. As an example, it means: “a” only, “b” only, “c” only, “a” and “b”, “a” and “c”, “b” and “c”, and/or “a”, “b”, and “c”.

As may also be used herein, the terms “processing module”, “processing circuit”, “processor”, “processing circuitry”, and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, processing circuitry, and/or processing unit may be, or further include, memory and/or an integrated memory element, which may be a single memory device, a plurality of memory devices, and/or embedded circuitry of another processing module, module, processing circuit, processing circuitry, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, processing circuitry, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, processing circuitry and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, processing circuitry and/or processing unit executes, hard coded and/or operational instructions corresponding to at least some of the steps and/or functions illustrated in one or more of the Figures. Such a memory device or memory element can be included in an article of manufacture.

One or more embodiments have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

In addition, a flow diagram may include a “start” and/or “continue” indication. The “start” and “continue” indications reflect that the steps presented can optionally be incorporated in or otherwise used in conjunction with one or more other routines. In addition, a flow diagram may include an “end” and/or “continue” indication. The “end” and/or “continue” indications reflect that the steps presented can end as described and shown or optionally be incorporated in or otherwise used in conjunction with one or more other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

The one or more embodiments are used herein to illustrate one or more aspects, one or more features, one or more concepts, and/or one or more examples. A physical embodiment of an apparatus, an article of manufacture, a machine, and/or of a process may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of one or more of the embodiments. A module implements one or more functions via a device such as a processor or other processing device or other hardware that may include or operate in association with a memory that stores operational instructions. A module may operate independently and/or in conjunction with software and/or firmware. As also used herein, a module may contain one or more sub-modules, each of which may be one or more modules.

As may further be used herein, a computer readable memory includes one or more memory elements. A memory element may be a separate memory device, multiple memory devices, or a set of memory locations within a memory device. Such a memory device may be a read-only memory, random access memory, volatile memory, non-volatile memory, static memory, dynamic memory, flash memory, cache memory, and/or any device that stores digital information. The memory device may be in a form a solid-state memory, a hard drive memory, cloud memory, thumb drive, server memory, computing device memory, and/or other physical medium for storing digital information.

While particular combinations of various functions and features of the one or more embodiments have been expressly described herein, other combinations of these features and functions are likewise possible. The present disclosure is not limited by the particular examples disclosed herein and expressly incorporates these other combinations.

What is claimed is:

1. A method for execution by one or more processing modules of one or more computing devices of a dispersed storage network (DSN), the method comprises:
receiving a write request for a data object;
encoding a data segment of the data object using a dispersed storage error coding function to produce a plurality of encoded data slices, wherein a data object is segmented to produce a plurality of data segments;
determining whether a write threshold number of storage units is available for storing the plurality of encoded data slices;
in response to determining that a write threshold number of storage units is available for storing the plurality of encoded data slices, identifying a write threshold number of storage units from the storage units available for storing the plurality of encoded data slices for storing at least a write threshold number of encoded data slices;
generating a vault source name for the data segment;
associating the vault source name of the data segment of the plurality of data segments with a data identifier; and
issuing write slice requests to the identified storage units, wherein each write slice request includes the vault source name and an associated encoded data slice of the write threshold number of encoded data slices.

2. The method of claim 1, further comprising:
in response to determining that a write threshold number of storage units is not available for storing the plurality of encoded data slices, identifying less than a write threshold number of storage units for storing at least a write threshold number of encoded data slices.

3. The method of claim 1, further comprising:
in response to determining that a write threshold number of storage units is not available for storing the plurality of encoded data slices selecting a write threshold minus one number of available storage units for storing at least a write threshold number of encoded data slices.

4. The method of claim 1, wherein the determining whether a write threshold number of storage units is available for storing the plurality of encoded data slices is based on at least one of an availability indicator, a write slice response, a query, a query response, and a predetermination.

5. The method of claim 1, wherein the generating a vault source name for the data segment is based on at least one of a vault identifier, a data identifier of the data object, and an object identifier associated with the data identifier.

6. The method of claim 1, wherein the associating the vault source name of the data segment of the plurality of data segments with a data identifier includes updating a DSN directory to associate a source name portion of a vault source name with the data ID.

7. The method of claim 1, wherein each write slice request further includes a pillar index number associated with a corresponding pillar index number of an information dispersal algorithm (IDA) width number of encoded data slices of the plurality of encoded data slices.

8. The method of claim 1, wherein the vault source name is identical for each write slice request.

9. The method of claim 1, wherein each write slice request further includes a slice name associated with each encoded data slice of the plurality of encoded data slices, wherein the slice name includes the vault source name.

10. A computer readable memory device comprises:
at least one memory section that stores operational instructions that, when executed by one or more processing modules of one or more computing devices of a dispersed storage network (DSN), causes the one or more computing devices to:
receive a write request for a data object;
encode a data segment of the data object using a dispersed storage error coding function to produce a plurality of encoded data slices, wherein a data object is segmented to produce a plurality of data segments;
determine whether a write threshold number of storage units is available for storing the write threshold number of encoded data slices;
in response to determination that a write threshold number of storage units is available for storing the plurality of encoded data slices, identify a write threshold number of storage units from the storage units available for storing the plurality of encoded data slices for storing at least a write threshold number of encoded data slices;
generate a vault source name for the data segment;
associate the vault source name of the data segment of the plurality of data segments with a data identifier; and
issue write slice requests to the identified storage units, wherein each write slice request includes the vault source name and an associated encoded data slice of the write threshold number of encoded data slices.

11. The computer readable memory device of claim 10, wherein the at least one memory section stores operational instructions that, when executed by one or more processing modules of one or more computing devices of a dispersed storage network (DSN), causes the one or more computing devices to:
in response to a determination that a write threshold number of storage units is not available for storing the plurality of encoded data slices, identify less than a write threshold number of storage units for storing at least a write threshold number of encoded data slices.

12. The computer readable memory device of claim 10, wherein the at least one memory section stores operational instructions that, when executed by one or more processing modules of one or more computing devices of a dispersed storage network (DSN), causes the one or more computing devices to:
in response to a determination that a write threshold number of storage units is not available for storing the plurality of encoded data slices, select a write threshold minus one number of available storage units for storing at least a write threshold number of encoded data slices.

13. The computer readable memory device of claim 10, wherein the determination whether a write threshold number of storage units is available for storing the plurality of encoded data slices is based on at least one of an availability indicator, a write slice response, a query, a query response, and a predetermination.

14. The computer readable memory device of claim 10, wherein the vault source name for the data segment is generated based on at least one of a vault identifier, a data identifier of the data object, and an object identifier associated with the data identifier.

15. The computer readable memory device of claim 10, wherein the vault source name of the data segment of the plurality of data segments is associated with a data identifier by updating a DSN directory to associate a source name portion of a vault source name with the data ID.

16. The computer readable memory device of claim 10, wherein each write slice request further includes a pillar index number associated with a corresponding pillar index number of an information dispersal algorithm (IDA) width number of encoded data slices of the plurality of encoded data slices.

17. The computer readable memory device of claim 10, wherein each write slice request further includes a pillar index number associated with a corresponding pillar index number of an information dispersal algorithm (IDA) width number of encoded data slices of the plurality of encoded data slices.

18. The computer readable memory device of claim 10, wherein the vault source name is identical for each write slice request.

19. The computer readable memory device of claim 10, wherein each write slice request further includes a slice name associated with each encoded data slice of the plurality of encoded data slices, wherein the slice name includes the vault source name.

20. A computing device comprises:
an interface; and
a processing module, when operable within the computing device, causes the computing device to:
receive a write request for a data object;
encode a data segment of the data object using a dispersed storage error coding function to produce a plurality of encoded data slices, wherein a data object is segmented to produce a plurality of data segments;
determine whether a write threshold number of storage units is available for storing the write threshold number of encoded data slices;
in response to determination that a write threshold number of storage units is available for storing the plurality of encoded data slices, identify a write threshold number of storage units from the storage units available for storing the plurality of encoded data slices for storing at least a write threshold number of encoded data slices;
generate a vault source name for the data segment;
associate the vault source name of the data segment of the plurality of data segments with a data identifier; and
issue write slice requests to the identified storage units, wherein each write slice request includes the vault source name and an associated encoded data slice of the write threshold number of encoded data slices.
